(19) United States
(12) Patent Application Publication
(10) Pub. No.: US 2026/0012142 A1
(43) Pub. Date: Jan. 8, 2026

(54) Wideband Amplifier and Method for Designing the Same

(71) Applicant: Alpha Networks inc., Hsinchu (TW)

(72) Inventors: YAO-JEN CHEN, Hsinchu (TW); Jiang-Xin Guo, Hsinchu (TW)

(21) Appl. No.: 19/231,121

(22) Filed: Jun. 6, 2025

(30) Foreign Application Priority Data
Jul. 2, 2024 (TW) 113124669

(51) Int. Cl. H03F 1/42; H03F 1/56

(52) U.S. Cl. CPC H03F 1/42; H03F 1/565; H03F 2200/294

(57) ABSTRACT

A method for designing wideband amplifier includes employing two common-source amplifiers based on an inductive source degeneration architecture and peripheral circuits connected thereto to build the wideband amplifier. Wherein, after impedance matching of the two common-source amplifiers and the peripheral circuits at a predetermined frequency is achieved, an inductor circuit is inserted between the two common-source amplifiers as a part of the wideband amplifier. After the insertion, the impedance of the inductor circuit is adjusted such that a gain variation of the wideband amplifier within a predetermined frequency band is not greater than a predetermined variation threshold. Thereafter, output impedance and input impedance of the wideband amplifier are adjusted to reduce signal reflection generated within the predetermined frequency band to realize designing of the wideband amplifier.

### FIELD OF THE INVENTION

The present invention relates to a wideband amplifier and method for designing the same. More particularly, the present invention relates to a wideband amplifier based on common-source amplifier and method for designing the same.

### BACKGROUND OF THE INVENTION

Along with the rapid development of communication market using 5G millimeter wave, demands for transmitting electronic data which require huge amount of traffic, such as images and sounds, are more and more common. Therefore, the design of a wideband, low-noise amplifier compatible with 5G communication systems represents a significant and valuable area of research.

### SUMMARY OF THE INVENTION

Accordingly, one of the objects of the present invention is to provide a method for designing a wideband amplifier, which enables the development of low-noise amplifiers suitable for wider bandwidth.

Another one of the objects of the present invention is to provide a wideband amplifier which achieves good gain performance across a wide bandwidth.

In one aspect of view, the present invention provides a method for designing a wideband amplifier, wherein the wideband amplifier amplifies signals received from a signal source and outputs the amplified signals from an amplifier output terminal, and the method is characterized in comprising: providing a first common-source amplifier based on an inductive source degeneration architecture, wherein the first common-source amplifier comprises a first transistor and a first peripheral circuit coupled to the first transistor; providing a second common-source amplifier based on the inductive source degeneration architecture, wherein the second common-source amplifier comprises a second transistor and a second peripheral circuit coupled to the second transistor; providing an output transmission circuit; performing a first configuration operation, wherein the first common-source amplifier, the second common-source amplifier and the output transmission circuit are sequentially configured such that, at a predetermined frequency, the signal source is impedance-matched to the first transistor through the first peripheral circuit, a first combination comprising the signal source and the first common-source amplifier is impedance-matched to the second transistor through the second peripheral circuit, and a second combination comprising the first combination and the second common-source amplifier is impedance-matched to the amplifier output terminal through the output transmission circuit; performing a second configuration operation after completing the first configuration operation, wherein an induction circuit is configured in the second peripheral circuit such that the first common-source amplifier is electrically coupled to the second common-source amplifier exclusively through the induction circuit; performing a third configuration operation after completing the second configuration operation, wherein the induction circuit is adjusted such that a gain variation of the wideband amplifier within a predetermined frequency band is not greater than a predetermined variation threshold; and, performing a fourth configuration operation after completing the third configuration operation, wherein the first peripheral circuit and the output transmission circuit is adjusted, such that, a first signal reflection occurring at a gate terminal of the first transistor within a first frequency sub-band is reduced, and a second signal reflection occurring at the amplifier output terminal within a second frequency sub-band is reduced, wherein, the predetermined frequency is within the predetermined frequency band.

In one embodiment, the first configuration operation comprises electrically coupling the first peripheral circuit to the signal source; electrically coupling the second peripheral circuit to the first transistor; electrically coupling the output transmission circuit between the second transistor and the amplifier output terminal; adjusting a first impedance of the first peripheral circuit such that the signal source is impedance-matched to the first transistor through the first peripheral circuit while transmitting electronic signals having the predetermined frequency; after adjusting the first impedance, adjusting a second impedance of the second peripheral circuit such that the first combination is impedance-matched to the second transistor through the second peripheral circuit while transmitting electronic signals having the predetermined frequency; and, after adjusting the second impedance, adjusting a third impedance of the output transmission circuit such that the second combination is impedance-matched to the amplifier output terminal through the output transmission circuit while transmitting electronic signals having the predetermined frequency.

In one embodiment, the first frequency sub-band ranges between the predetermined frequency and a highest frequency of the predetermined frequency band, and the second frequency sub-band ranges between the predetermined frequency and a lowest frequency of the predetermined frequency band.

In another aspect of view, the present invention provides a wideband amplifier adapted to amplifying signals received from a signal source and outputting the amplified signals from an amplifier output terminal, wherein the wideband amplifier is characterized in comprising: a first transistor comprising a first control terminal, a first current-carrying terminal and a second current-carrying terminal, wherein establishment of electrical conduction between the first and second current-carrying terminals is determined by signals applied to the first control terminal; a second transistor comprising a second control terminal, a third current-carrying terminal and a fourth current-carrying terminal, wherein establishment of electrical conduction between the third and fourth current-carrying terminals is determined by signals applied to the second control terminal; a first capacitor comprising a first terminal of the first capacitor and a second terminal of the first capacitor, wherein the first terminal of the first capacitor is electrically coupled to the signal source; a first inductor comprising a first terminal of the first inductor and a second terminal of the first inductor, wherein the first terminal of the first inductor is electrically coupled to the second terminal of the first capacitor; a second inductor comprising a first terminal of the second inductor and a second terminal of the second inductor, wherein the first terminal of the second inductor is electrically coupled to the second terminal of the first inductor, and the second terminal of the second inductor is electrically coupled to the first control terminal; a first resistor comprising a first terminal of the first resistor and a second terminal of the first resistor, wherein the first terminal of the first resistor is electrically coupled to the second terminal of the first inductor and the first terminal of the second inductor, and the second terminal of the first resistor is electrically coupled to a first control voltage source; a third inductor comprising a first terminal of the third inductor and a second terminal of the third inductor, wherein the first terminal of the third inductor is electrically coupled to the second current-carrying terminal, and the second terminal of the third inductor is grounded; a fourth inductor comprising a first terminal of the fourth inductor and a second terminal of the fourth inductor, wherein the first terminal of the fourth inductor is electrically coupled to the first current-carrying terminal; a fifth inductor comprising a first terminal of the fifth inductor and a second terminal of the fifth inductor, wherein the first terminal of the fifth inductor is electrically coupled to the second terminal of the fourth inductor, and the second terminal of the fifth inductor is electrically coupled to a first working voltage source; a sixth inductor comprising a first terminal of the sixth inductor and a second terminal of the sixth inductor, wherein the first terminal of the sixth inductor is electrically coupled to the second terminal of the fourth inductor and the first terminal of the fifth inductor; a second capacitor comprising a first terminal of the second capacitor and a second terminal of the second capacitor, wherein the first terminal of the second capacitor is electrically coupled to the second terminal of the sixth conductor; a seventh inductor comprising a first terminal of the seventh inductor and a second terminal of the seventh inductor, wherein the first terminal of the seventh inductor is electrically coupled to the second terminal of the second capacitor, and the second terminal of the seventh inductor is electrically coupled to the second control terminal; a second resistor comprising a first terminal of the second resistor and a second terminal of the second resistor, wherein the first terminal of the second resistor is electrically coupled to the second terminal of the seventh inductor and the second control terminal, and the second terminal of the second resistor is electrically coupled to a second control voltage source; an eighth inductor comprising a first terminal of the eighth inductor and a second terminal of the eighth inductor, wherein the first terminal of the eighth inductor is electrically coupled to the fourth current-carrying terminal, and the second terminal of the eighth inductor is grounded; a ninth inductor comprising a first terminal of the ninth inductor and a second terminal of the ninth inductor, wherein the first terminal of the ninth inductor is electrically coupled to the third current-carrying terminal; a tenth inductor comprising a first terminal of the tenth inductor and a second terminal of the tenth inductor, wherein the first terminal of the tenth inductor is electrically coupled to the second terminal of the ninth inductor, and the second terminal of the tenth inductor is electrically coupled to a second working voltage source; and, a third capacitor comprising a first terminal of the third capacitor and a second terminal of the third capacitor, wherein the first terminal of the third capacitor is electrically coupled to the second terminal of the ninth inductor and the first terminal of the tenth inductor, and the second terminal of the third capacitor is electrically coupled to the amplifier output terminal.

In one embodiment, the first control voltage source comprises: a voltage supplier comprising a positive terminal and a negative terminal, wherein the positive terminal is electrically coupled to the second terminal of the first resistor, and the negative terminal is grounded; and, a voltage stabilizing capacitor comprising a first stabilizing terminal and a second stabilizing terminal, wherein the first stabilizing terminal is electrically coupled to the second terminal of the first resistor and the positive terminal, and the second stabilizing terminal is grounded.

In one embodiment, the first working voltage source comprises: a voltage supplier comprising a positive terminal and a negative terminal, wherein the positive terminal is electrically coupled to the second terminal of the fifth inductor, and the negative terminal is grounded; and, a voltage stabilizing capacitor comprising a first stabilizing terminal and a second stabilizing terminal, wherein the first stabilizing terminal is electrically coupled to the second terminal of the fifth inductor and the positive terminal, and the second stabilizing terminal is grounded.

In one embodiment, the second control voltage source comprises: a voltage supplier comprising a positive terminal and a negative terminal, wherein the positive terminal is electrically coupled to the second terminal of the second resistor, and the negative terminal is grounded; and, a voltage stabilizing capacitor comprising a first stabilizing terminal and a second stabilizing terminal, wherein the first stabilizing terminal is electrically coupled to the second terminal of the second resistor and the positive terminal, and the second stabilizing terminal is grounded.

In one embodiment, the second working voltage source comprises: a voltage supplier comprising a positive terminal and a negative terminal, wherein the positive terminal is electrically coupled to the second terminal of the tenth inductor, and the negative terminal is grounded; and, a voltage stabilizing capacitor comprising a first stabilizing terminal and a second stabilizing terminal, wherein the first stabilizing terminal is electrically coupled to the second terminal of the tenth inductor and the positive terminal, and the second stabilizing terminal is grounded.

In summary, the method for designing wideband amplifier provided by the present invention firstly combines two common-source amplifiers in the way making the two common-source amplifiers to be impedance matched at a specific frequency. After that, an induction circuit is inserted between the two common-source amplifiers and the elements of the induction circuit are adjusted such that the gain of the wideband amplifier remains stable across a required frequency band. Finally, impedance matching is applied to the entire circuit to minimize signal reflection at both the input and output terminals. The wideband amplifier developed by the design method described above provides good gain performance across the required bandwidth and is very suitable for being implemented in 5G and other communication systems operating across various frequency bands.

### BRIEF DESCRIPTION OF THE DRAWINGS

The invention will become more readily apparent to those ordinarily skilled in the art after reviewing the following detailed description and accompanying drawings, in which:

FIG. 1 is a flow chart of the method for designing a wideband amplifier in accordance with one embodiment of the present invention;

FIG. 2 is a flow chart of performing the first configuration operation of the method for designing a wideband amplifier in accordance with one embodiment of the present invention;

FIG. 3 is a circuitry block diagram of a wideband amplifier in accordance with one embodiment of the present invention, in which impedance matching is performed for a predetermined frequency;

FIG. 4 is a circuitry block diagram of the wideband amplifier shown in FIG. 3 after performing the second configuration operation in accordance with one embodiment of the present invention; and

FIG. 5 is a detailed circuitry diagram of a wideband amplifier in accordance with one embodiment of the present invention.

### DETAILED DESCRIPTION OF PREFERRED EMBODIMENTS

The invention will now be described more specifically with reference to the following embodiments. It is to be noted that the following descriptions of preferred embodiments of this invention are presented herein for the purpose of illustration and description only. It is not intended to be exhaustive or to be limited to the precise form disclosed.

It is also noted that, in order to make the description be easily understood by those with ordinary skill in the art, “a first unit is electrically coupled to a second unit” means that electronic signals can be transmitted between the first unit and the second unit, and, unless other limitations are made, transmission of the electronic signals might be unidirectional or bidirectional, and transmitting method of the electronic signals might be wired or wireless.

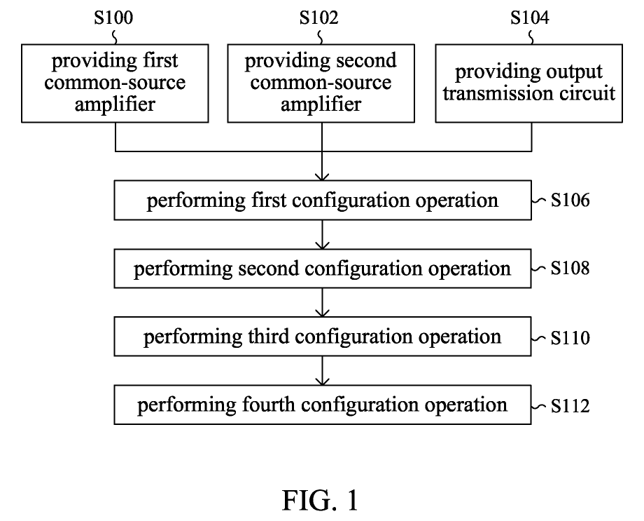

Please refer to FIG. 1, which is a flow chart of the method for designing a wideband amplifier in accordance with one embodiment of the present invention. Because the wideband amplifier is developed from two common-source amplifiers based on the inductive source degeneration architecture in this embodiment, some basic circuits forming the basis of the wideband amplifier are established from steps S100, S102 and S104. As shown in the figure, a first common-source amplifier, which is going to be electrically coupled to the signal source to receive and amplify an input signal, is provided through step S100. A second common-source amplifier, which is going to be electrically coupled to the first common-source amplifier to receive and amplify a result output from the first common-source amplifier, is provided through step S102. An output transmission circuit, which is going to be electrically coupled between the second common-source amplifier and an amplifier output terminal to transmit the result output from the second common-source amplifier to the amplifier output terminal, is provided through step S104. Therefore, three basic circuits of the wideband amplifier, comprising the first and second common-source amplifiers and the output transmission circuit, are obtained by performing steps S100 ~ S104.

In this embodiment, after obtaining the three basic circuits, the flow proceeds to step S106 to achieve a first impedance-matching for the wideband amplifier by performing a first configuration operation. Specifically, the object of the first impedance-matching is to ensure that the wideband amplifier remains in an impedance-matched state when transmitting an electronic signal having a specific frequency (hereinafter referred to as predetermined frequency). This objective is achieved by dividing the first configuration operation into three stages and completing these stages sequentially.

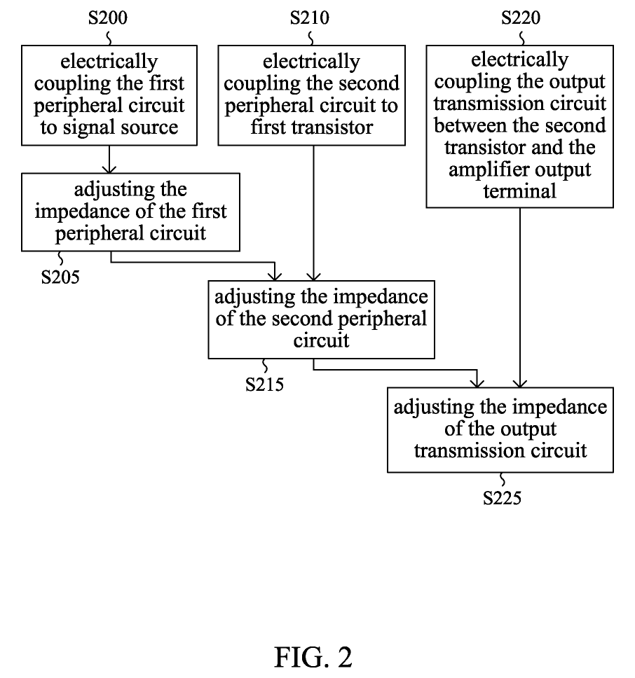

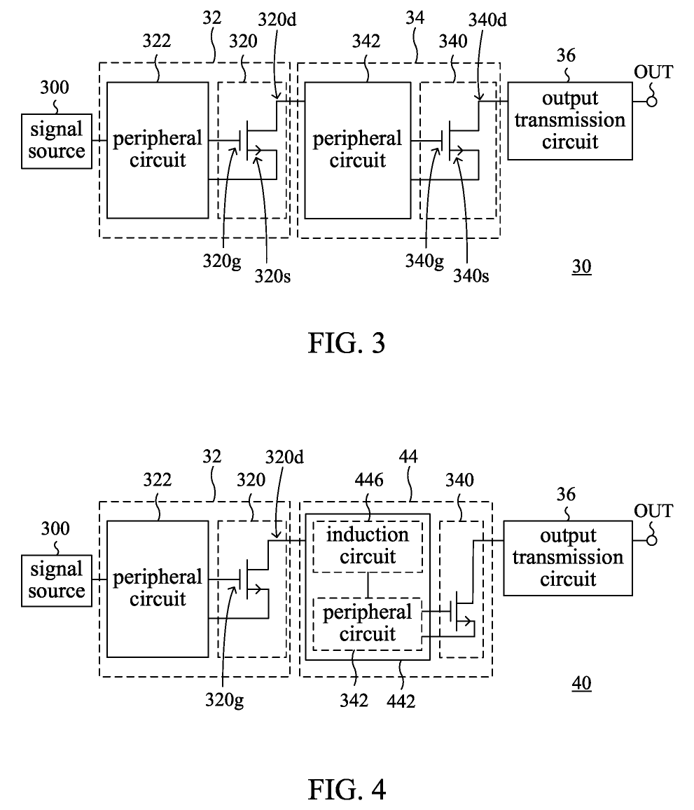

Please refer to FIG. 2, which is a flow chart of performing the first configuration operation of the method for designing the wideband amplifier in accordance with one embodiment of the present invention. Furthermore, to describe the technique concept of the present invention in a clear and simple way, please also refer to FIG. 3, which is a circuitry block diagram of a wideband amplifier in accordance with one embodiment of the present invention, in which impedance matching is performed for the predetermined frequency. It is noted that the phrase “impedance matching is performed for the predetermined frequency” means that the wideband amplifier is configured to remain in impedance-matched state while transmitting an electronic signal having the predetermined frequency, which corresponds to the first configuration operation mentioned above.

As shown in FIG. 3, the wideband amplifier 30 comprises a common-source amplifier 32 (hereinafter also referred to as first common-source amplifier), a common-source amplifier 34 (hereinafter also referred to as second common-source amplifier), and an output transmission circuit 36. The common-source amplifier 32 comprises a transistor 320 (hereinafter also referred to as first transistor) and a peripheral circuit 322 (hereinafter also referred to as first peripheral circuit) which is electrically coupled to the transistor 320. The common-source amplifier 34 comprises a transistor 340 (hereinafter also referred to as second transistor) and a peripheral circuit 342 (hereinafter also referred to as second peripheral circuit) which is electrically coupled to the transistor 340. Each of the transistors 320 and 340 comprises a control terminal and two current-carrying terminals, wherein establishment of electrical conduction between the two current-carrying terminals of a same one transistor is determined by signals applied to the control terminal of the same one transistor. For example, the control terminal could be the gate of a MOSFET or the base of a BJT, and the two current-carrying terminals could be the source and the drain of the MOSFET or the emitter and collector of the BJT. To simplify the description of the present invention, the control terminal and the two current-carrying terminals are hereinafter referred to as the gate terminal, the source terminal, and the drain terminal, respectively. However, those with ordinary skill may readily apply the technique concept described herein to other types of transistors, and the present invention should not be construed as being limited thereto.

It should be noted that, when various electronic components are in use, they are electrically coupled to each other. Conversely, components that are not currently in use are not necessarily forced to be electrically coupled with those that are in use. Furthermore, as is known to those skilled in the art, in order to simplify the design process of a wideband amplifier, simulation software may be appropriately used in place of actual electronic components and physical electrical coupling relationships. The present invention does not impose any limitations in this regard.

In order to ensure that the wideband amplifier 30 meets the requirements of subsequent use, the first stage of this embodiment is to perform impedance matching between the signal source 300 and the transistor 320. To achieve the impedance matching operation performed in the first stage, the peripheral circuit 322 in the common-source amplifier 32 is electrically coupled to the signal source 300 in step S200. Subsequently, the impedance matching operation is carried out by adjusting the impedance of the peripheral circuit 322 in step S205 such that impedance matching of the signal source 300 to the gate terminal 320g of the transistor 320 could be achieved through the peripheral circuit 322 while transmitting the electronic signal having the predetermined frequency. As is known by those with ordinary skill in the art, the process of impedance matching may involve referring to a Smith Chart and S-parameter diagrams to adjust the impedance of the electronic components. The related details are therefore omitted herein for brevity.

After completing the impedance matching operation of the first stage, the second stage in this embodiment involves impedance matching the combination of the common-source amplifier 32 and the signal source 300 to the transistor 340. To complete the impedance matching operation performed in the second stage, the peripheral circuit 342 of the common-source amplifier 34 is electrically coupled to the transistor 320 in step S210. Subsequently, the impedance matching operation of the second stage is carried out by adjusting the impedance of the peripheral circuit 342 in step S215 such that impedance matching of the combination of the signal source 300 and the common-source amplifier 32 to the gate terminal 340g of the transistor 340 could be achieved through the peripheral circuit 342 while transmitting the electronic signal having the predetermined frequency.

After completing the impedance matching operation of the second stage, the third stage in this embodiment involves impedance matching the combination of the signal source 300, the common-source amplifier 32, and the common-source amplifier 34 to the amplifier output terminal OUT. To complete the impedance matching operation performed in the third stage, the output transmission circuit 36 is electrically coupled between the transistor 340 and the amplifier output terminal OUT in step S220. Subsequently, the impedance matching operation of the third stage is carried out by adjusting the impedance of the output transmission circuit 36 in step 225 such that impedance matching of the combination of signal source 300, the common-source amplifier 32, and the common-source amplifier 34 to the amplifier output terminal OUT could be achieved through the output transmission circuit 36 while transmitting the electronic signal having the predetermined frequency.

Upon completion of the operations in steps S200 ~ S225, the wideband amplifier 30 is capable of achieving the effect intended by the first configuration operation, that is, maintaining an impedance-matched state during the transmission of the electronic signal having the predetermined frequency. At this stage, the signal source 300 is electrically coupled to the gate terminal 320g of the transistor 320 through the peripheral circuit 322, the source terminal 320s of the transistor 320 is electrically coupled to ground through the peripheral circuit 322, the drain terminal 320d is electrically coupled to the gate terminal 340g of the transistor 340 through the peripheral circuit 342, the source terminal 340s of the transistor 340 is electrically coupled to ground through the peripheral circuit 342, and the drain terminal 340d of the transistor 340 is electrically coupled to the amplifier output terminal OUT through the output transmission circuit 36. It should be noted that those with ordinary skill in the art may adopt other known techniques to carry out the first configuration operation, as long as the intended effect of the first configuration operation can still be achieved, depending on practical needs. The implementation of the present invention is not limited to the technical details described in the embodiments.

Please refer to FIG. 1 and FIG. 3. After completing the operations in step S106, the flow proceeds to step S108 to perform a second configuration operation which adds an induction circuit into the common-source amplifier 34 and configures the induction circuit in such a way that the common-source amplifier 32 is electrically coupled to the transistor 340 exclusively through the induction circuit.

Please refer to FIG. 4, which is a circuitry block diagram of the wideband amplifier shown in FIG. 3 after performing the second configuration operation in accordance with one embodiment of the present invention. The elements or circuit blocks shown in FIG. 4 that are assigned the same reference numerals as those in FIG. 3 perform the same or similar functions as their counterparts in FIG. 3, and thus, detailed descriptions thereof will not be described in detail hereinafter. The elements or circuit blocks comprise the signal source 300, the common-source amplifier 32, the transistor 340 in the common-source amplifier 44, and the output transmission circuit 36.

As shown in FIG. 4, after incorporating the induction circuit 446 added in step S108, the original common-source amplifier 34 shown in FIG. 3 becomes the new common-source amplifier 44, wherein the induction circuit 446, together with the peripheral circuit 342 of the common-source amplifier 34, constitutes the peripheral circuit 442 of the new common-source amplifier 44, and the coupling between the portion derived from the peripheral circuit 342 and the transistor 340 remains unchanged. The main difference between the wideband amplifier 30 shown in FIG. 3 and the wideband amplifier 40 shown in FIG. 4 is the connection configuration of the transistor 320, wherein, in the wideband amplifier 30, the transistor 320 is electrically coupled directly to the peripheral circuit 342, whereas in the wideband amplifier 40, the transistor 320 is electrically coupled to the peripheral circuit 342 through the induction circuit 446.

Please refer to FIG. 1 again. After completing the second configuration operation in step S108, the flow proceeds to step S110 to perform a third configuration operation. The third configuration operation is performed to keep the gain variation of the wideband amplifier 40 within a predetermined variation threshold, such as within 3 decibels (dB), across a specific frequency range, hereinafter referred to as the predetermined frequency band, by adjusting the impedance of the induction circuit 446.

When the frequency range adopted in fifth-generation (5G) communication technology (approximately 20 GHz to 34 GHz) is used as the predetermined frequency band applicable to the wideband amplifier 40, this embodiment suggests selecting a mid-range frequency within 20 GHz to 34 GHz, such as 27 GHz, as the predetermined frequency. Under such a selection, completing the aforementioned first configuration operation allows the wideband amplifier 30 to be in an impedance-matched state when transmitting the electronic signal with a frequency of 27 GHz. After completing the second configuration operation, which involves adding the induction circuit to transform the wideband amplifier 30 into the wideband amplifier 40, and after performing the third configuration operation to appropriately adjust the induction circuit, the gain variation of the wideband amplifier 40 within the predetermined frequency band of 20 GHz to 34 GHz can be kept within 3 dB.

It should be noted that although the predetermined frequency and the predetermined frequency band could be unrelated, such a selection may render the previously performed impedance matching operation based on the predetermined frequency meaningless. Therefore, selecting the predetermined frequency from within the frequency range covered by the predetermined frequency band is suggested in this embodiment.

After completing the aforementioned third configuration operation, the flow proceeds to step S112 to perform a fourth configuration operation, wherein the fourth configuration operation adjusts the impedance of the peripheral circuit 322 and the output transmission circuit 36 to reduce signal reflection occurring at the gate terminal 320g and at the amplifier output terminal OUT.

To reduce signal reflection, the predetermined frequency band is first divided into two frequency sub-bands having different frequency ranges. Then, by adjusting the impedance of the peripheral circuit 322, signal reflection occurring at the gate terminal 320g of the transistor 320 can be reduced when the signal source 300 provides a signal having a frequency within one of the frequency sub-bands to the common-source amplifier 32. Similarly, by adjusting the impedance of the output transmission circuit 36, signal reflection occurring at the amplifier output terminal OUT can be reduced when the common-source amplifier 44 provides a signal having a frequency within the other frequency sub-band to the amplifier output terminal OUT.

It should be noted that the frequency ranges of the two frequency sub-bands could be determined by technicians according to practical requirements. For example, one of the frequency sub-bands could be defined as extending from the highest frequency of the predetermined frequency band down to a predetermined dividing frequency, while the other frequency is extending from the predetermined dividing frequency down to the lowest frequency of the predetermined frequency band.

Taking the frequency range used in the 5G communication technology and the predetermined frequency of 27 GHz as an example, one of the frequency sub-bands may be defined as ranging from 34 GHz to 27 GHz, while the other frequency sub-band is defined as ranging from 27 GHz to 20 GHz. In this case, the fourth configuration operation performed in step S112 adjusts the impedance of the peripheral circuit 322 to reduce signal reflection occurring at the gate terminal 320g when transmitting a signal having any frequency within 34 GHz–27 GHz. Similarly, the fourth configuration operation also adjusts the impedance of the output transmission circuit 36 to reduce signal reflection occurring at the amplifier output terminal OUT when transmitting a signal having any frequency within 27 GHz–20 GHz.

Although the embodiments described above reduce signal reflection of higher-frequency signals at the input side and reduce signal reflection of lower-frequency signals at the output side, it is also possible to achieve other signal reflection adjustment patterns by tuning the impedance of the peripheral circuit 322 and the output transmission circuit 36 based on the teachings of the present invention. For example, the impedance can be adjusted to reduce signal reflection of lower-frequency signals at both the input and output sides, to reduce signal reflection of higher-frequency signals at both the input and output sides, or to reduce signal reflection of lower-frequency signals at the input side and higher-frequency signals at the output side. The variations can be achieved by those with ordinary skill in the art in accordance with practical requirements and in light of the disclosure discussed above, and thus will not be further described herein.

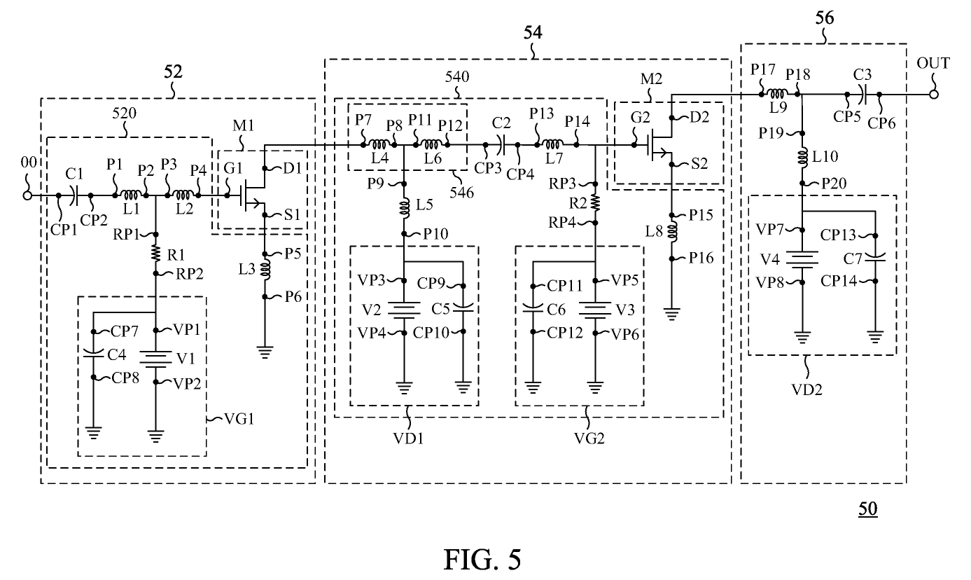

Please refer to FIG. 5, which is a detailed circuitry diagram of a wideband amplifier in accordance with one embodiment of the present invention. In this embodiment, the wideband amplifier 50 receives an input signal from the signal source 300, amplifies the input signal, and outputs the amplified input signal to the outside through the amplifier output terminal OUT. As shown in the figure, the wideband amplifier 50 comprises a common-source amplifier 52, a common-source amplifier 54 and an output transmission circuit 56. The common-source amplifier 52 comprises a transistor M1 and a peripheral circuit 520 which further comprises a capacitor C1, three inductors L1, L2 and L3, a resistor R1 and a control voltage source VG1. In the common-source amplifier 52, a first terminal CP1 of the capacitor C1 is electrically coupled to the signal source 300, a second terminal CP2 of the capacitor C1 is electrically coupled to a first terminal P1 of the inductor L1, a second terminal P2 of the inductor L1 is electrically coupled to a first terminal P3 of the inductor L2 and a first terminal RP1 of the resistor R1, a second terminal RP2 of the resistor R1 is electrically coupled to the control voltage source VG1, a second terminal P4 of the inductor L2 is electrically coupled to a gate terminal G1 of the transistor M1, a source terminal S1 of the transistor M1 is electrically coupled to a first terminal P5 of the inductor L3, a second terminal P6 of the inductor L3 is grounded, and a drain terminal D1 of the transistor M1 is electrically coupled to the common-source amplifier 54.

Furthermore, in this embodiment, the common-source amplifier 54 comprises a transistor M2 and a peripheral circuit 540. As shown in the figure, the peripheral circuit 540 comprises an induction circuit 546 that is added while performing the second configuration operation, and the components that were installed during the first configuration operation, including three inductors L5, L7 and L8, a capacitor C2, a resistor R2, a working voltage source VD1 and a control voltage source VG2. The induction circuit 546 comprises two inductors L4 and L6. In the common-source amplifier 54, a first terminal P8 of the inductor L4 is electrically coupled to the drain terminal D1 of the transistor M1, a second terminal P8 of the inductor L4 is electrically coupled to a first terminal P11 of the inductor L6 and a first terminal P9 of the inductor L5, a second terminal P10 of the inductor L5 is electrically coupled to the working voltage source VD1, a second terminal P12 of the inductor L6 is electrically coupled to a first terminal CP3 of the capacitor C2, a second terminal CP4 of the capacitor C2 is electrically coupled to a first terminal P13 of the inductor L7, a second terminal P14 of the inductor L7 is electrically coupled to a gate terminal G2 of the transistor M2 and a first terminal RP3 of the resistor R2, a second terminal RP4 of the resistor R2 is electrically coupled to the control voltage source VG2, a source terminal S2 of the transistor M2 is electrically coupled to a first terminal P15 of the inductor L8, a second terminal P16 of the inductor L8 is grounded, and a drain terminal D2 of the transistor M2 is electrically coupled to the output transmission circuit 56.

In this embodiment, the output transmission circuit 56 comprises two inductors L9 and L10, a capacitor C3 and a working voltage source VD2. A first terminal P17 of the inductor L9 is electrically coupled to the drain terminal D2 of the transistor M2, a second terminal P18 of the inductor L9 is electrically coupled to a first terminal CP5 of the capacitor C3 and a first terminal P19 of the inductor L10, a second terminal P20 of the inductor L10 is electrically coupled to the working voltage source VD2, and a second terminal CP6 of the capacitor C3 is electrically coupled to the amplifier output terminal OUT.

In the circuit shown in FIG. 5, the capacitors C1, C2 and C3 serve as DC-blocking capacitors without impeding high-frequency signal transmission. Furthermore, in this embodiment, each voltage source comprises a voltage supplier and a voltage stabilizing capacitor. As shown in FIG. 5, the control voltage source VG1 comprises a voltage supplier V1 and a voltage stabilizing capacitor C4, wherein a positive terminal VP1 of the voltage supplier V1 is electrically coupled to the second terminal RP2 of the resistor R1 and a first terminal CP7 of the voltage stabilizing capacitor C4, and both a negative terminal VP2 of the voltage supplier V1 and a second terminal CP8 of the voltage stabilizing capacitor C4 are grounded. The working voltage source VD1 comprises a voltage supplier V2 and a voltage stabilizing capacitor C5, wherein a positive terminal VP3 of the voltage supplier V2 is electrically coupled to the second terminal P10 of the inductor L5 and a first terminal CP9 of the voltage stabilizing capacitor C5, and both a negative terminal VP4 of the voltage supplier V2 and a second terminal CP10 of the voltage stabilizing capacitor C5 are grounded. The control voltage source VG2 comprises a voltage supplier V3 and a voltage stabilizing capacitor C6, wherein a positive terminal VP5 of the voltage supplier V3 is electrically coupled to the second terminal RP4 of the resistor R2 and a first terminal CP11 of the voltage stabilizing capacitor C6, and both a negative terminal VP6 of the voltage supplier V3 and a second terminal CP12 of the voltage stabilizing capacitor C6 are grounded. The working voltage source VD2 comprises a voltage supplier V4 and a voltage stabilizing capacitor C7, wherein a positive terminal VP7 of the voltage supplier V4 is electrically coupled to the second terminal P20 of the inductor L10 and a first terminal CP13 of the voltage stabilizing capacitor C7, and both a negative terminal VP8 of the voltage supplier V4 and a second terminal CP14 of the voltage stabilizing capacitor C7 are grounded.

It is noted that each of the voltage sources mentioned above could be implemented using any suitable electronic components, without being limited to the circuit provided in this embodiment. The structures of the voltage sources could also be different from one another, and such variations can be adjusted by those with ordinary skill in the art according to practical requirements.

By applying the technique solutions described above, the method for designing wideband amplifier provided by the present invention first combines two common-source amplifiers in the way making the two common-source amplifiers to be impedance matched at a specific frequency. After that, an induction circuit is inserted between the two common-source amplifiers and the elements of the induction circuit are adjusted such that the gain of the wideband amplifier remains stable across a required frequency band. Finally, impedance matching is applied to the entire circuit to minimize signal reflection at both the input and output terminals. The wideband amplifier developed by the design method described above provides good gain-performance across the required bandwidth and is very suitable for being implemented in 5G and other communication systems operating across various frequency bands.

What is claimed is:

1. A method for designing a wideband amplifier, wherein the wideband amplifier amplifies signals received from a signal source and outputs the amplified signals from an amplifier output terminal, and the method is characterized in comprising:
providing a first common-source amplifier based on an inductive source degeneration architecture, wherein the first common-source amplifier comprises a first transistor and a first peripheral circuit coupled to the first transistor;
providing a second common-source amplifier based on the inductive source degeneration architecture, wherein the second common-source amplifier comprises a second transistor and a second peripheral circuit coupled to the second transistor;
providing an output transmission circuit;
performing a first configuration operation, wherein the first common-source amplifier, the second common-source amplifier and the output transmission circuit are sequentially configured such that, at a predetermined frequency, the signal source is impedance-matched to the first transistor through the first peripheral circuit, a first combination comprising the signal source and the first common-source amplifier is impedance-matched to the second transistor through the second peripheral circuit, and a second combination comprising the first combination and the second common-source amplifier is impedance-matched to the amplifier output terminal through the output transmission circuit;
performing a second configuration operation after completing the first configuration operation, wherein an induction circuit is configured in the second peripheral circuit such that the first common-source amplifier is electrically coupled to the second common-source amplifier exclusively through the induction circuit;
performing a third configuration operation after completing the second configuration operation, wherein the induction circuit is adjusted such that a gain variation of the wideband amplifier within a predetermined frequency band is not greater than a predetermined variation threshold; and
performing a fourth configuration operation after completing the third configuration operation, wherein the first peripheral circuit and the output transmission circuit is adjusted such that a first signal reflection occurring at a gate terminal of the first transistor within a first frequency sub-band and a second signal reflection occurring at the amplifier output terminal within a second frequency sub-band is reduced,
wherein, the predetermined frequency is within the predetermined frequency band.

2. The method according to claim 1, wherein the first configuration operation comprises:
electrically coupling the first peripheral circuit to the signal source;
electrically coupling the second peripheral circuit to the first transistor;
electrically coupling the output transmission circuit between the second transistor and the amplifier output terminal;
adjusting a first impedance of the first peripheral circuit such that the signal source is impedance-matched to the first transistor through the first peripheral circuit while transmitting electronic signals having the predetermined frequency;
after adjusting the first impedance, adjusting a second impedance of the second peripheral circuit such that the first combination is impedance-matched to the second transistor through the second peripheral circuit while transmitting electronic signals having the predetermined frequency; and
after adjusting the second impedance, adjusting a third impedance of the output transmission circuit such that the second combination is impedance-matched to the amplifier output terminal through the output transmission circuit while transmitting electronic signals having the predetermined frequency.

3. The method according to claim 1, wherein the first frequency sub-band ranges between the predetermined frequency and a highest frequency of the predetermined frequency band, and the second frequency sub-band ranges between the predetermined frequency and a lowest frequency of the predetermined frequency band.

4. A wideband amplifier adapted to amplifying signals received from a signal source and outputting the amplified signals from an amplifier output terminal, wherein the wideband amplifier is characterized in comprising:
a first transistor comprising a first control terminal, a first current-carrying terminal and a second current-carrying terminal, wherein establishment of electrical conduction between the first and second current-carrying terminals is determined by signals applied to the first control terminal;
a second transistor comprising a second control terminal, a third current-carrying terminal and a fourth current-carrying terminal, wherein establishment of electrical conduction between the third and fourth current-carrying terminals is determined by signals applied to the second control terminal;
a first capacitor comprising a first terminal of the first capacitor and a second terminal of the first capacitor, wherein the first terminal of the first capacitor is electrically coupled to the signal source;
a first inductor comprising a first terminal of the first inductor and a second terminal of the first inductor, wherein the first terminal of the first inductor is electrically coupled to the second terminal of the first capacitor;
a second inductor comprising a first terminal of the second inductor and a second terminal of the second inductor, wherein the first terminal of the second inductor is electrically coupled to the second terminal of the first inductor, and the second terminal of the second inductor is electrically coupled to the first control terminal;
a first resistor comprising a first terminal of the first resistor and a second terminal of the first resistor, wherein the first terminal of the first resistor is electrically coupled to the second terminal of the first inductor and the first terminal of the second inductor, and the second terminal of the first resistor is electrically coupled to a first control voltage source;
a third inductor comprising a first terminal of the third inductor and a second terminal of the third inductor, wherein the first terminal of the third inductor is electrically coupled to the second current-carrying terminal, and the second terminal of the third inductor is grounded;
a fourth inductor comprising a first terminal of the fourth inductor and a second terminal of the fourth inductor, wherein the first terminal of the fourth inductor is electrically coupled to the first current-carrying terminal;
a fifth inductor comprising a first terminal of the fifth inductor and a second terminal of the fifth inductor, wherein the first terminal of the fifth inductor is electrically coupled to the second terminal of the fourth inductor, and the second terminal of the fifth inductor is electrically coupled to a first working voltage source;
a sixth inductor comprising a first terminal of the sixth inductor and a second terminal of the sixth inductor, wherein the first terminal of the sixth inductor is electrically coupled to the second terminal of the fourth inductor and the first terminal of the fifth inductor;
a second capacitor comprising a first terminal of the second capacitor and a second terminal of the second capacitor, wherein the first terminal of the second capacitor is electrically coupled to the second terminal of the sixth conductor;
a seventh inductor comprising a first terminal of the seventh inductor and a second terminal of the seventh inductor, wherein the first terminal of the seventh inductor is electrically coupled to the second terminal of the second capacitor, and the second terminal of the seventh inductor is electrically coupled to the second control terminal;
a second resistor comprising a first terminal of the second resistor and a second terminal of the second resistor, wherein the first terminal of the second resistor is electrically coupled to the second terminal of the seventh inductor and the second control terminal, and the second terminal of the second resistor is electrically coupled to a second control voltage source;
an eighth inductor comprising a first terminal of the eighth inductor and a second terminal of the eighth inductor, wherein the first terminal of the eighth inductor is electrically coupled to the fourth current-carrying terminal, and the second terminal of the eighth inductor is grounded;
a ninth inductor comprising a first terminal of the ninth inductor and a second terminal of the ninth inductor, wherein the first terminal of the ninth inductor is electrically coupled to the third current-carrying terminal;
a tenth inductor comprising a first terminal of the tenth inductor and a second terminal of the tenth inductor, wherein the first terminal of the tenth inductor is electrically coupled to the second terminal of the ninth inductor, and the second terminal of the tenth inductor is electrically coupled to a second working voltage source; and
a third capacitor comprising a first terminal of the third capacitor and a second terminal of the third capacitor, wherein the first terminal of the third capacitor is electrically coupled to the second terminal of the ninth inductor and the first terminal of the tenth inductor, and the second terminal of the third capacitor is electrically coupled to the amplifier output terminal.

5. The wideband amplifier according to claim 4, wherein the first control voltage source comprises:
a voltage supplier comprising a positive terminal and a negative terminal, wherein the positive terminal is electrically coupled to the second terminal of the first resistor, and the negative terminal is grounded; and
a voltage stabilizing capacitor comprising a first stabilizing terminal and a second stabilizing terminal, wherein the first stabilizing terminal is electrically coupled to the second terminal of the first resistor and the positive terminal, and the second stabilizing terminal is grounded.

6. The wideband amplifier according to claim 4, wherein the first working voltage source comprises:
a voltage supplier comprising a positive terminal and a negative terminal, wherein the positive terminal is electrically coupled to the second terminal of the fifth inductor, and the negative terminal is grounded; and
a voltage stabilizing capacitor comprising a first stabilizing terminal and a second stabilizing terminal, wherein the first stabilizing terminal is electrically coupled to the second terminal of the fifth inductor and the positive terminal, and the second stabilizing terminal is grounded.

7. The wideband amplifier according to claim 4, wherein the second control voltage source comprises:
a voltage supplier comprising a positive terminal and a negative terminal, wherein the positive terminal is electrically coupled to the second terminal of the second resistor, and the negative terminal is grounded; and
a voltage stabilizing capacitor comprising a first stabilizing terminal and a second stabilizing terminal, wherein the first stabilizing terminal is electrically coupled to the second terminal of the second resistor and the positive terminal, and the second stabilizing terminal is grounded.

8. The wideband amplifier according to claim 4, wherein the second working voltage source comprises:
a voltage supplier comprising a positive terminal and a negative terminal, wherein the positive terminal is electrically coupled to the second terminal of the tenth inductor, and the negative terminal is grounded; and
a voltage stabilizing capacitor comprising a first stabilizing terminal and a second stabilizing terminal, wherein the first stabilizing terminal is electrically coupled to the second terminal of the tenth inductor and the positive terminal, and the second stabilizing terminal is grounded.
